(19) United States
(12) Patent Application Publication
(10) Pub. No.: US 2017/0178993 A1
(43) Pub. Date: Jun. 22, 2017

(54) Electronic component and methods of manufacturing the same

(71) Applicant: Infineon Technologies AG, Neuniberg (DE)

(72) Inventors: Thorsten MEYER, Regensburg (DE); Edward Fuergut, Dasing (DE); Gerald Ofner, Regensburg (DE); Petteri Palm, Regensburg (DE)

(21) Appl. No.: 15/382,693

(22) Filed: Dec. 18, 2016

(30) Foreign Application Priority Data
Dec. 18, 2015 (DE) 10 2015 122 282.5

(51) Int. Cl. H01L 23/31; H01L 21/78; H01L 23/00; H01L 21/56

(52) U.S. Cl. CPC H01L 23/3157; H01L 21/568; H01L 21/78; H01L 24/17; H01L 24/09; H01L 2924/01029

(57) ABSTRACT

An electronic component which comprises an electrically insulating layer having at least one through hole, a patterned electrically conductive structure at least partially on the electrically insulating layer, an electronic chip electrically coupled with the patterned electrically conductive structure, an encapsulant at least partially encapsulating the electronic chip, and at least one electrically conductive contact structure at least partially in the at least one through hole in contact with at least part of the patterned electrically conductive structure.

### BACKGROUND OF THE INVENTION

Field of the Invention

The present invention relates to an electronic component and methods of manufacturing an electronic component.

Description of the Related Art

Packages may be denoted as encapsulated electronic chips with electrical connects extending out of the encapsulant and being mounted to an electronic periphery, for instance on a printed circuit board.

Packaging cost is an important driver for the industry. Related with this are performance, dimensions and reliability. The different packaging solutions are manifold and have to address the needs of the application. There are applications, where high performance is required, others, where reliability is the top priority—but all requires lowest possible cost.

### SUMMARY OF THE INVENTION

There may be a need to manufacture electronic components in a simple and reliable manner.

According to an exemplary embodiment, an electronic component is provided which comprises an electrically insulating layer having at least one through hole, a patterned electrically conductive structure at least partially on the electrically insulating layer, an electronic chip (such as a semiconductor chip) electrically coupled with the patterned electrically conductive structure, an encapsulant at least partially encapsulating the electronic chip, and at least one electrically conductive contact structure at least partially in the at least one through hole in (in particular in physical) contact with at least part of the patterned electrically conductive structure.

According to another exemplary embodiment, a method of manufacturing an electronic component is provided which comprises forming at least part of a patterned electrically conductive structure at least partially on or above an electrically insulating layer, electrically coupling an electronic chip with the patterned electrically conductive structure, at least partially encapsulating the electronic chip by an encapsulant, removing material of the electrically insulating layer to thereby form at least one through hole, and forming at least one electrically conductive contact structure at least partially in the at least one through hole in contact with at least part of the patterned electrically conductive structure.

According to yet another exemplary embodiment, a method of manufacturing a plurality of electronic components is provided which comprises forming a patterned electrically conductive structure on a temporary carrier (in particular a carrier which may be used temporarily and not forming part of a finished product such as a package), electrically coupling a plurality of electronic chips with the patterned electrically conductive structure, at least partially encapsulating the electronic chips and the patterned electrically conductive structure by an encapsulant, removing the temporary carrier (in particular after the encapsulating), forming a plurality of electrically conductive contact structures in contact with at least part of the patterned electrically conductive structure, and singularizing an obtained body (i.e. a body obtained after the previous procedures including the forming of the plurality of electrically conductive contact structures) into the plurality of separate electronic components, each of which comprising part of the patterned electrically conductive structure, part of the encapsulant, at least one of a plurality of electronic chips, and at least one of a plurality of electrically conductive contact structures.

According to an exemplary embodiment of the invention, an electronic component such as a package is provided which can be manufactured in a very simple batch procedure and which shows a high reliability in operation as well as a proper performance in terms of electrical behaviour and mechanical robustness. In a corresponding manufacturing procedure, one or more electronic chips (such as semiconductor chips) may be mounted above a dielectric layer which may be covered on at least one main surface thereof—already at this stage or later—by an electrically conductive structure. The electronic chips mounted over the electrically insulating layer are then already in a proper condition for a subsequent encapsulation procedure by which the electronic chips are electrically insulated, mechanically protected and immobilized. Already previously or now, the electrically insulating layer may be opened by the formation of one or more through holes at one or more appropriate positions so as to obtain access to the electric contacts of the electronic chips on a side opposing an exposed surface of the encapsulant. Via this one or more through hole, it is possible to electrically contact the one or more electronic chips through the electrically insulating layer from a back side.

If desired, and as particularly advantageous in the context of a batch manufacturing procedure in which mechanical stability may be an issue, it is possible that the electrically insulating layer is arranged and supported on a temporary carrier during part of the manufacture so as to avoid undesired bending or the like during the mounting and encapsulation as well as contactation procedures. When access to the main surface of the electronic chip facing the electrically insulating layer is desired, such a temporary carrier may be removed so as to expose a main surface of the electrically insulating layer for further processing.

The described procedure is very simple and is compatible with a manufacturing architecture in which only one single patterning procedure of patterning electrically conductive material is sufficient. Furthermore, the procedure involves standard processes so that existing equipment and technology can be used for manufacturing packaged electronic chips in a simple procedure. At the same time, the manufactured electronic components allow a reliable and robust electric contactation compatible also with requirements of high voltage and high current values as may occur in certain applications such as power semiconductor devices.

### DESCRIPTION OF FURTHER EXEMPLARY EMBODIMENTS

In the following, further exemplary embodiments of the electronic component and the methods will be explained.

In an embodiment, the method further comprises at least partially encapsulating the patterned electrically conductive structure and/or the at least one electrically conductive contact structure with the encapsulant. The procedure of at least partially encapsulating the at least one electronic chip and at least partially encapsulating the patterned electrically conductive structure and/or at least partially encapsulating the at least one electrically conductive contact structure may be combined to a single simultaneous procedure. This renders the manufacturing procedure simple and fast. Encapsulating the electronic chip and the patterned electrically conductive structure and/or the electrically conductive contact structure may also involve an underfill to thereby prevent undesired gaps within the electronic component or package which might deteriorate the heat removal capability. In an alternative procedure, the process of encapsulating only embeds the electronic chip in the encapsulant, whereas the patterned electrically conductive structure and/or the electrically conductive contact structure may then remain unencapsulated or may be encapsulated separately by another encapsulant.

In an embodiment, the method further comprises forming the patterned electrically conductive structure on or above a temporary carrier (in particular before the encapsulating), and removing the temporary carrier after the encapsulating. The use of a temporary carrier for supporting the usually relatively thin electrically insulating layer and the material mounted and deposited above can further improve the reliability of the manufactured electronic components, as well as reproducibility of their properties. The temporary carrier may support the electrically insulating layer on a main surface thereof opposing the mounting surface of the electrically insulating layer on which the one or more electronic chips are mounted. This temporary carrier may be removed from the remainder of the manufactured body or electronic component when access to the mentioned external main surface of the electrically insulating layer is desired for further processing purposes, in particular when one or more through holes shall be formed in the electrically insulating layer for accessing electric contacts on the chip surface facing the electrically insulating layer.

In an embodiment, the method comprises carrying out the procedures of forming the patterned electrically conductive structure, electrically coupling, at least partially encapsulating, removing, and forming the at least one electrically conductive contact structure for manufacturing a plurality of electronic components in a batch procedure (in particular using an artificial substrate (e. g. wafer or panel) formed of multiple separate electronic chips and material of the encapsulant), and singularizing an obtained body into the plurality of separate electronic components, each of which comprising part of the electrically insulating layer, part of the patterned electrically conductive structure, part of the encapsulant, at least one of the electronic chips, and at least one of the electrically conductive contact structures. Thus, the described manufacturing architecture is compatible with a batch manufacturing of multiple electronic components at the same time. In such an embodiment, all the described procedures may be carried out with one and the same body which is then, at the very end, singularized into the individual electronic components. This is a very efficient manufacturing procedure allowing to increase yield and reduce costs while ensuring homogeneous properties of all manufactured electronic components. Singularizing may be accomplished, for example, by sawing, cutting, etching, etc.

In an embodiment, the material of the electrically insulating layer is removed for through hole formation by drilling, in particular by laser drilling. Drilling an electrically insulating layer such as a plastic foil is very efficiently possible by a corresponding laser treatment with low costs, high through-put and in a short time. As an alternative to laser drilling, mechanical drilling, etching, etc. are possible as well.

In an embodiment, the method further comprises removing part of the encapsulant after its formation and curing, in particular to expose a main surface of the electronic chip or for thinning the electronic component. In such an optional procedure of removing part of the encapsulant, a specifically thin and compact configuration of the electronic component may be obtained. Furthermore, the surface of the electronic chip opposing the electrically insulating layer may be exposed to an environment, for instance to further improve thermal management, since a cooling body may then be contacted directly to the exposed surface of the heat generating electronic chip. Also an exposure of the mentioned main surface of the electronic chip for electric contacting purposes is possible with such a procedure. The removal of the material of the encapsulant may for example be accomplished by mechanical material removal, for instance by grinding and/or polishing and/or etching. Alternative possibilities is the removal of material of the encapsulant by etching, by laser ablation, etc. The grinding step may be followed by a polishing step and/or an etch of the silicon in order to remove scratches caused by the grinding/polishing step.

In an embodiment, the encapsulating is carried out to underfill a gap or void between the electronic chip on the one hand and the electrically insulating layer and the patterned electrically conductive structure on the other hand. With such an underfill, it is possible to fill even small gaps between electrically insulating layer, patterned electrically conductive structure and/or the embedded electronic chip with material so as to prevent any gas inclusions in an interior of the package. This is advantageous in terms of heat removal capability, because gas inclusions may function as substantially thermally insulating regions. Also the mechanical properties of the package may be improved by such an underfill. The underfill may for instance be formed by encapsulating the gaps or voids with liquid material which is then hardened or cured, as for instance possible with molding. The procedure may also include, in addition to the underfilling, overfilling the electronic chip. Underfilling and overfilling may be done in one single procedure, or in two subsequent procedures.

In an embodiment, the patterned electrically conductive structure may be formed by only a single patterning procedure. In contrast to conventional approaches, one single patterning procedure (see FIG. 2) may be sufficient for forming a redistribution structure (see FIG. 9) between small chip dimensions and larger dimensions of a printed circuit board or the like. This is efficient in terms of resources and manufacturing time. Particularly efficient and accurate is the formation of a thin electrically conductive base layer, which is subsequently patterned with high precision as a result of the thin layer thickness, followed by a selective deposition (in particular by plating) of additional electrically conductive material on the patterned layer. In another scenario, in which rapid processing is more important than high spatial accuracy, the patterned electrically conductive structure may be formed by the formation of a thick electrically conductive layer, which is subsequently patterned to complete formation of the patterned electrically conductive structure in a subtractive way.

In an embodiment, the temporary carrier comprises a metal plate. For example, such a metal plate may be a relatively thin aluminum sheet which can be removed at an appropriate stage of the manufacturing procedure when access to the free main surface of the electrically insulating layer is desired. Alternatively, the temporary carrier may be also made of a removable sheet which can be reused for a subsequent batch manufacturing procedure. For instance, the temporary carrier may hence also be a ceramic sheet, a plastic sheet, etc.

In an embodiment, the temporary carrier is removed by etching. During such an etching procedure, the electrically insulating layer may serve as a stop layer. Thus, selective etching may be implemented. Alternatively, the temporary carrier may be removed by a mechanical ablation procedure such as grinding. Further alternatively, the temporary carrier may be removed by peeling (for instance by implementing a release layer between the temporary carrier and the electrically insulating layer).

In an embodiment, the encapsulant at least partially encapsulates the patterned electrically conductive structure. A corresponding manufacturing procedure is shown in FIG. 1 to FIG. 8. Encapsulating the patterned electrically conductive structure is particularly advantageously implemented when the patterned electrically conductive structure is arranged on the same main surface of the electrically insulating layer on or above which also the one or more electronic chips are mounted.

In an embodiment, the electronic chip is mounted on the patterned electrically conductive structure in a flip chip configuration. Such a flip chip configuration is particularly advantageous in terms of the manufacturing architecture according to an exemplary embodiment of the invention because a chip surface with electric contacts on an active chip side may be located very close to the electrically insulating layer via which the electric contactation of the active chip surface can be accomplished. In a corresponding mounting method, the chip may be flipped face down so that a chip surface with its active side directly faces the electrically insulating layer, and preferably also faces the patterned electrically conductive structure to be contacted with such chip pads.

In an embodiment, the patterned electrically conductive structure is configured as a patterned double layer stack. Configuring the patterned electrically conductive structure as a double layer allows to provide it with a sufficient physical thickness so as to achieve a low ohmic coupling with the chip pads. At the same time, such a double layer configuration may be formed with a single metal patterning procedure. For example, this is possible by forming a mask on a continuous homogeneous electrically conductive base layer, wherein additional electrically conductive material may be deposited, for instance by plating, on exposed areas of the electrically conductive layer while other surface portions will not be covered with additional electrically conductive material. After removal of the mask, it is then possible to back etch the resulting electrically conductive structure so as to obtain a patterned electrically conductive structure with a single metallization patterning procedure only. Thus, as compared to conventional approaches, the effort for the formation of a reliably thick patterned electrically conductive structure with high spatial accuracy may be significantly reduced.

More generally, it is possible to form such a double layer stack of electrically conductive material by a semi-additive process, by an additive process or by a subtractive process.

Alternatively, the patterned electrically conductive structure may be configured as a patterned single layer. Although etching a single thick layer may result in a smaller accuracy of the defined structures, it may be manufactured with lower effort (and hence with lower costs) than the above mentioned more accurate double layer.

In an embodiment, the electronic component comprises an electrically conductive intermediate structure (which may be an additional structure separate from the electrically conductive contact structure—see for instance FIG. 1 to FIG. 9—, or which may alternatively form part of or even constitute the above-mentioned electrically conductive contact structure—see for instance FIG. 10 to FIG. 13) spacing and electrically coupling the electronic chip with regard to the patterned electrically conductive structure. Such an electrically conductive intermediate structure may be pre-connected to the electronic chip prior to the mounting. Alternatively, the electrically conductive intermediate structure may be formed after mounting of the electronic chip on the electrically insulating layer, for instance partially or fully extending through the through-holes in the electrically insulating layer.

In an embodiment, the electrically conductive intermediate structure comprises at least one of the group consisting of a pillar and a solder structure. Such pillars or posts may for example be made of copper and may be directly arranged on chip pads of the electronic chip, in particular on a main surface of an electronic chip corresponding to its active side. It is however also possible that the electrically conductive intermediate structure is a solder structure (for instance configured as solder balls or bumps) which already provide the basis for mounting and electrically connecting the manufactured electronic component on a base structure such as a printed circuit board by soldering.

In an embodiment, the electronic chip is a power semiconductor chip. In particular for power semiconductor chips, electric reliability and heat removal capability are important issues which can be met with the described manufacturing procedure. Possible integrated circuit elements which can be monolithically integrated in such a semiconductor power chip are field effect transistors (such as insulated gate bipolar transistors or metal oxide semiconductor field effect transistors) diodes, etc. With such constituents, it is possible to provide electronic components usable as packages for automotive applications, high-frequency applications, etc. Examples for electric circuits which can be constituted by such and other power semiconductor circuits and packages are half-bridges, full bridges, etc.

In an embodiment, the encapsulant comprises at least one of the group consisting of a mold compound and a laminate.

In an embodiment, the encapsulant comprises a laminate, in particular a printed circuit board laminate. In the context of the present application, the term “laminate structure” may particularly denote an integral flat member formed by electrically conductive structures and/or electrically insulating structures which may be connected to one another by applying a pressing force. The connection by pressing may be optionally accompanied by the supply of thermal energy. Lamination may hence be denoted as the technique of manufacturing a composite material in multiple layers. A laminate can be permanently assembled by heat and/or pressure and/or welding and/or adhesives.

In another embodiment, the encapsulant comprises a mold, in particular a plastic mold. For instance, a correspondingly encapsulated chip may be provided by placing the electronic chip (if desired together with other components) between an upper mold die and a lower mold die and to inject liquid mold material therein. After solidification of the mold material, the package formed by the encapsulant with the electronic chip in between is completed. If desired, the mold may be filled with particles improving its properties, for instance its heat removal properties.

In an embodiment, the electrically insulating layer comprises at least one of the group consisting of a single layer, a layer stack, a polymer, a laminate, and a mold compound, in particular a mold compound filled with filler particles. Hence, substantially any dielectric structure may be used as the electrically insulating layer providing support, reliable electric insulation and being patternable to form through holes therethrough to enable the above described electric contactation.

In an embodiment, a surface portion of the electronic chip is exposed and uncovered by the encapsulant. Such a structure can be obtained for instance by grinding away material of an encapsulant during full circumferential encapsulation of the electronic chip. Alternatively, the encapsulation may leave free a surface portion of the electronic chip from the very beginning or a sacrificial material can be used, which is removed. Exposing a surface of the electronic chip may be advantageous for electric contactation purposes, heat removal purposes or to obtain a specifically thin package or electronic component.

In an embodiment, the patterned electrically conductive structure is arranged vertically in between the electrically insulating layer and the electronic chip. Such an architecture is shown in FIG. 1 to FIG. 8 and allows to protect the patterned electrically conductive structure within the encapsulant—from a mechanical and electrical point of view—with regard to an environment.

In another embodiment, the electrically insulating structure is arranged vertically in between the patterned electrically conductive structure and the electronic chip. In such an alternative configuration (see for instance FIG. 10 to FIG. 13), the patterned electrically conductive structure is exposed to an environment rather than facing the electronic chip on the main surface of the electrically insulating layer on which it is mounted. This allows to closely locate and electrically contact the patterned electrically conductive structure, for instance via solder structures, to an electronic periphery device such as a printed circuit board.

In an embodiment, the patterned electrically conductive structure is configured as at least part of a redistribution layer forming an interface between chip pads and a larger dimensioned exterior electric interface to be coupled to an electronic periphery. The patterned electrically conductive structure may hence serve as a redistribution layer and may translate between the tiny pads of the electronic chip and the larger dimensions of external electric contacts of a PCB or the like. In other words, the small dimensions of the chip world are transferred by the redistribution layer into the larger dimensions of the world of the mounting basis such as printed circuit boards on which the electronic component or package may be mounted. This results in a specifically compact design of the manufactured package, since a separate redistribution layer becomes dispensable.

In an embodiment, the electronic component comprises one or more solder structures (such as solder balls) on an exterior surface of the patterned electrically conductive structure. Such a solder structure may allow to mount the electronic component on an external periphery device such as a printed circuit board.

The one or more electronic chips may be semiconductor chips, in particular dies. In an embodiment, the at least one electronic chip is configured as a power semiconductor chip, in particular comprising at least one of the group consisting of a diode, and a transistor, more particularly an insulated gate bipolar transistor. In an embodiment, the device is configured as a power module. For instance, the one or more electronic chips may be used as semiconductor chips for power applications for instance in the automotive field. In an embodiment, at least one electronic chip may comprise a logic IC or an electronic chip for RF power applications. In one embodiment, the electronic chip(s) may be used as one or more sensors or actuators in microelectromechanical systems (MEMS), for example as pressure sensors or acceleration sensors.

As substrate or wafer for the electronic chips, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 to FIG. 8 show different structures obtained during carrying out a method of manufacturing electronic components according to an exemplary embodiment.

FIG. 9 shows electronic components according to an exemplary embodiment manufactured in accordance with a method described referring to FIG. 1 to FIG. 8.

FIG. 10 to FIG. 12 show different structures obtained during carrying out a method of manufacturing an electronic component according to another exemplary embodiment.

FIG. 13 shows an electronic component according to another exemplary embodiment manufactured in accordance with a method described referring to FIG. 10 to FIG. 12.

### DETAILED DESCRIPTION OF EXEMPLARY EMBODIMENTS

The illustration in the drawing is schematically and not to scale.

Before exemplary embodiments will be described in more detail referring to the figures, some general considerations will be summarized based on which exemplary embodiments have been developed.

According to an exemplary embodiment, an electronic component is provided which is configured as a flip-chip package with a low cost substrate. More specifically, an exemplary embodiment of the invention provides a package type which may serve well for low cost flip chip applications from all requirement points of view and also has advantages against classical packages.

One exemplary embodiments applies only one metallization layer and does not need a grinding step for the release of the metallization layer. Cost of the substrate may be strongly reduced this way.

According to a manufacturing method of an exemplary embodiment, a flip chip die may be applied on a carrier system with a single layer metallization on a dielectric layer. Subsequently, the component may be embedded into the mold compound, the carrier may be, and the metallization may be released from a bottom side, in particular by etching.

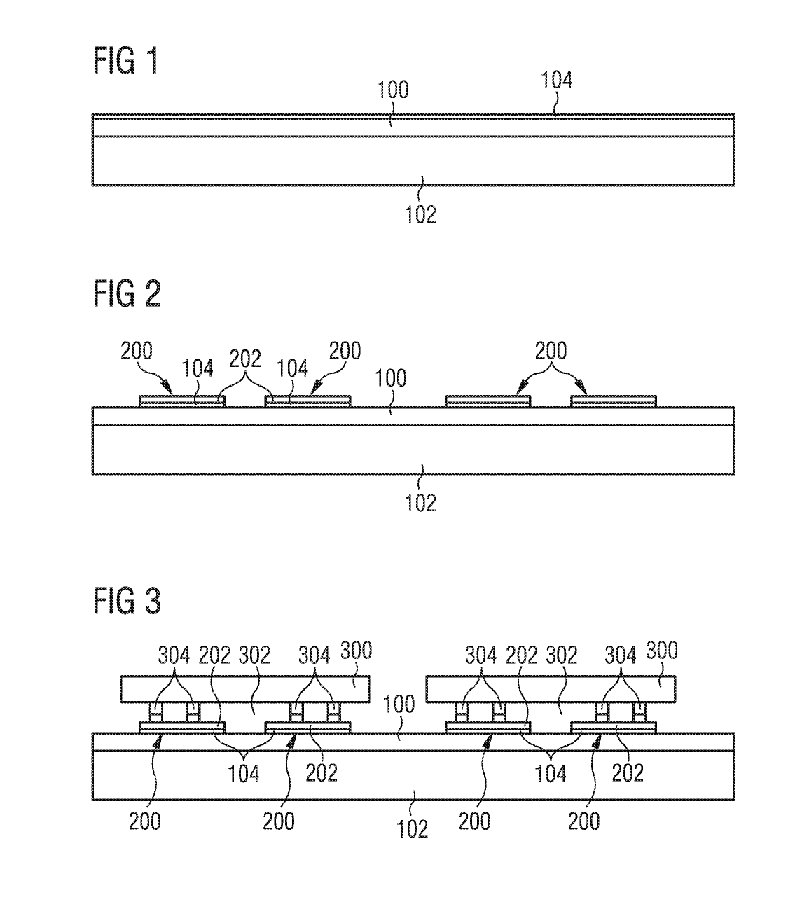

The starting point of an exemplary embodiment (see for example FIG. 1 to FIG. 9) may be a metal plate as temporary carrier, covered with a dielectric or electrically insulating layer and a metal seed layer. The dielectric layer may be any polymer, a laminate, a mold compound, etc., and it can be filled with filler particles or not. For example, the copper thickness of the seed layer can be chosen from thicknesses like 3 μm, 5 μm, 9 μm, 12 μm, 17.5 μm, 35 μm, 70 μm, 105 μm, or 150 μm. Depending on the required line/space, final copper thickness requirement and the selected copper thickness of the preform, the copper (or more generally metal) layer can be structured using a semi-additive process (for instance pattern plating, electroplating inside a photoresist, followed by a seed layer etch, wherein a copper seed layer thickness may be below 3 μm or even below 1 μm and in particular in a range between 1 μm and 12 μm so as to allow fast removal by etching) or with a subtractive process (for instance etching of copper with a thickness of for example larger than 17.5 μm). Result of this procedure is the formation of a patterned electrically conductive structure. Electronic chips, which may be configured as flip chip dies (for example with copper pillars or solder bumps or similar), may then be attached to the traces of the patterned electrically conductive structure, for example in mass reflow, thermos-compression bonding, gluing, or the like.

Subsequently, the attached flip chip dies may then be undermolded or underfilled and overmolded or film-molded by an encapsulant. After this, the construction may carry itself, so that the metal plate (acting as temporary carrier) is no longer needed. The metal plate can be removed, for example by an etching step, although this may be done later in the process flow as well. Another option, in addition to the provision of a metal carrier, is to attach the preform (copper-polymer laminate) on a temporary carrier (made of metal or polymer), for example with a release tape, which can be released by the addition of energy (e. g. thermal energy, chemical energy, etc.). Such a tape may be usually adhesive and may lose its adhesive properties (completely or partially) when heated above a threshold temperature of for instance 170° C. The polymer material of the electrically insulating layer in the construction may serve as protection for metal during the etch process. Optionally, a grinding process can now be performed, in order to release the die backside or to thin the package (for instance if film-molding was not used before).

Subsequently, the polymer material of the electrically insulating layer may be removed at the positions of the later applied solder balls. The copper metallization constituting the patterned electrically conductive structure may serve as stopping layer for the laser. Solder paste or solder balls may be attached into the openings or through holes of the electrically insulating layer (which may serve as solder stop). Thereafter, the structure may be separated to form multiple singularized electronic components. In an embodiment, also multi-die packages are possible.

In various embodiments, the format of the carrier/metal structures can be for example round or rectangular.

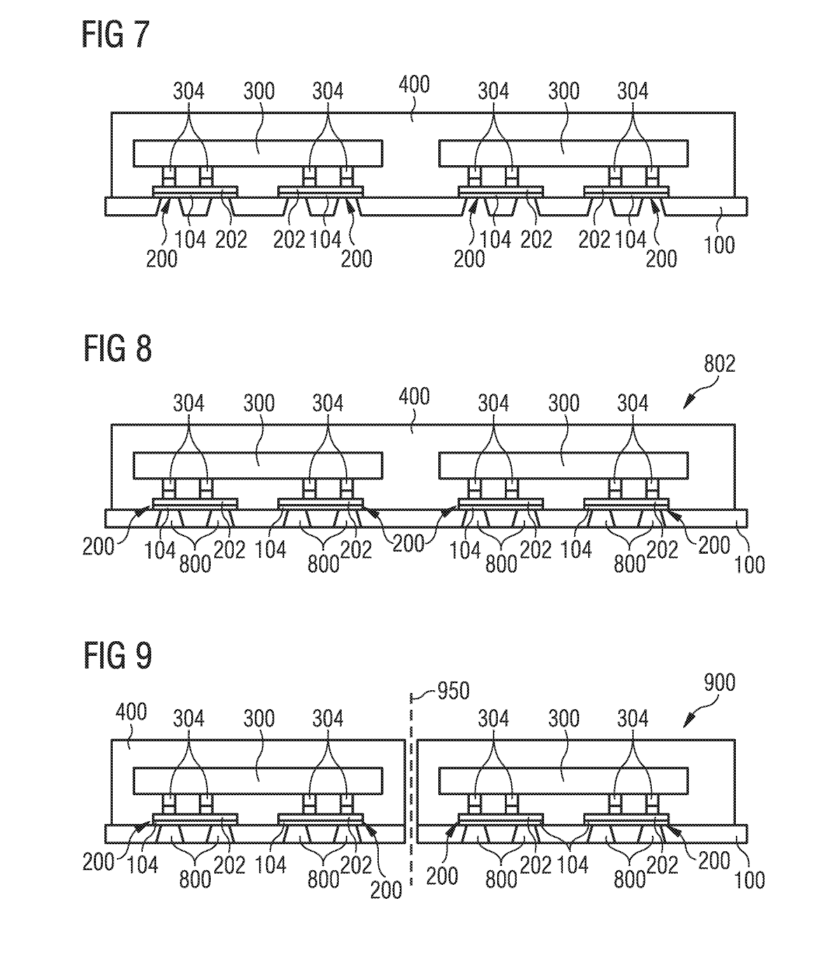

Starting point of the manufacturing process according to another exemplary embodiment (see also FIG. 10 to FIG. 13) may be a carrier (for example a copper carrier) with a structured polymer, as electrically insulating layer having through holes, on top. An electronic chip, preferably a flip chip die, may then be attached to the carrier via the through holes and an electrically conductive contact structure extending therethrough, for example by thermo-compression bonding or mass reflow or gluing. The die may then be undermolded by an encapsulant. After this, the carrier (such as a copper layer) can be thinned and/or structured to form a redistribution layer forming a patterned electrically conductive structure. Solder balls may be attached to the patterned electrically conductive structure, and the electronic components or packages can then be separated.

As already mentioned above, the format of the carrier/metal structures can be for example round or rectangular.

FIG. 1 to FIG. 8 show different structures obtained during carrying out a method of manufacturing electronic components 900 according to an exemplary embodiment.

As can be taken from FIG. 1, starting point of the manufacturing method is a metal (e. g. aluminum) plate as temporary carrier 102 with a polymer as electrically insulating layer 100 thereon. A copper layer (as seed layer), which here embodies an electrically conductive layer 104, is arranged on the electrically insulating layer 100. The polymer can also be a mold compound or a multi-layer material. The electrically insulating layer 100 can be stiff or flexible (for instance above a glass transition temperature) and can be filled or not.

In order to obtain a structure shown in FIG. 2, a patterned electrically conductive structure 200 is formed on the electrically insulating layer 100 and on the basis of the electrically conductive layer 104. More specifically, a double layer stack is provided as the patterned electrically conductive structure 200 and is composed of the patterned electrically conductive layer 104 and additional electrically conductive material denoted with reference numeral 202 and located above the patterned electrically conductive layer 104. To obtain the structure shown in FIG. 2, the copper layer or electrically conductive layer 104 may be masked with an appropriate material (for instance a photoresist material), followed by a plating procedure by which the additional electrically conductive material shown with reference numeral 202 is formed. The electrically conductive layer 104, which may be denoted as seed layer, may also comprise more than one layer. While this seed layer may be a single layer in some embodiments, the seed layer may for example comprise or consist of an adhesion promotor layer (e. g. titanium or titanium-tungsten) and a plating layer (e. g. copper) in another embodiment. After removing the mask, the seed layer in form of the electrically conductive layer 104 is removed at its exposed portions, thereby leaving the double layer stack of electrically conductive material shown as patterned electrically conductive structure 200. This procedure allows to obtain finest dimensions, advantageously thick copper traces and also multi-layer redistribution layers.

In order to obtain a structure shown in FIG. 3, electronic chips 300 (for instance power semiconductor chips) are mounted on and are electrically coupled with the patterned electrically conductive structure 200. More specifically, the dies embodying the electronic chips 300 are attached to the structure shown in FIG. 2 so that intermediate electrically conductive structures 304 bridge and electrically connect chip pads of the electronic chips 300 with the upper surface portions of the patterned electrically conductive structure 200. The electronic chips 300 may be mounted face down in flip chip attachment architecture, wherein for example mass reflow may be used for the attachment. For example, it is possible to use copper pillars, stud bumps or solder bumps/balls as electrically conductive intermediate structures 304.

In order to obtain a structure shown in FIG. 4, the electronic chips 300, the patterned electrically conductive structure 200 and the electrically conductive intermediate structures 304 are encapsulated by an encapsulant 400, which can be a mold compound (if desired comprising filler particles, for example for increasing thermal conductivity, so as to improve the capability of removing heat generated by the electronic chips 300 during operation). In the shown embodiment, the encapsulating is carried out to underfill gaps or voids 302 (compare FIG. 3) between the electronic chips 300 on the one hand and the electrically insulating layer 100 and the patterned electrically conductive structure 200 on the other hand. Forming the encapsulant 400 may for instance be accomplished by capillary underfill application (e. g. dispensing) or by a molded underfill procedure. However, it is also possible to perform overmolding (for example capillary UF plus overmolding), and also no-flow underfill can be used.

In order to obtain a structure shown in FIG. 5, the temporary carrier 102 may be removed, for instance by etching. After having cured the encapsulant 400, the structure above the temporary carrier 102 has become self-supporting and mechanically stable so that the temporary carrier 102 can now be removed.

In order to obtain a structure shown in FIG. 6, part of the material of the encapsulant 400 can be optionally removed from a top side of the structure shown in FIG. 5 to expose a main surface of the electronic chip 300 and for thinning purposes to increase compactness. Hence, FIG. 6 illustrates the result of an optional grinding procedure. If desired or required, the molded substrate shown in FIG. 5 can be thinned. Alternatively, such a thinning procedure may also be carried out prior to the removal of the temporary carrier 102.

In order to obtain a structure shown in FIG. 7 (which can be directly obtained based on the structure shown in FIG. 5 without the optional thinning procedure described referring to FIG. 6), material of the electrically insulating layer 100 is removed by laser drilling to thereby form a plurality of through holes 700. For obtaining the structure shown in FIG. 7, the vias are drilled as through-holes 700 into the polymer material of the electrically insulating layer 100 in order to make a redistribution structure accessible from the bottom side. Alternatively, also an etching procedure is possible for forming the through holes 700. The mentioned redistribution function may be accomplished by the patterned electrically conductive structure 200.

In order to obtain a structure shown in FIG. 8, a plurality of electrically conductive contact structures 800, here embodied as solder structures, are formed in the through holes 700 so as to directly contact assigned portions of the patterned electrically conductive structure 200. Thus, the procedure shown in FIG. 8 may be a solder attach procedure, wherein solder balls or solder paste can be attached as electrically conductive contact structures 800.

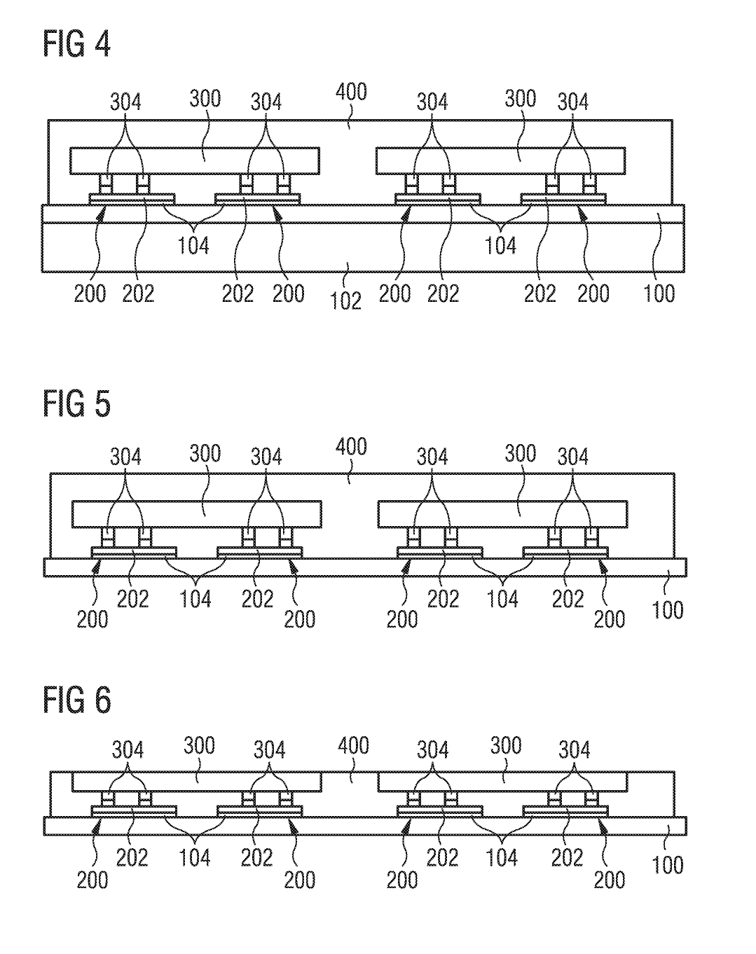

In order to obtain the electronic components 900 shown in FIG. 9, body 802 shown in FIG. 8 is separated by sawing into the plurality of separate electronic components 900. Separation lines 950 are selected so that each of the singularized electronic components 900 comprise a portion of the patterned electrically conductive structure 200, a portion of the encapsulant 400, one (or more) of the electronic chips 300, and some of the electrically conductive contact structures 800. FIG. 9 hence shows electronic components 900 according to an exemplary embodiment manufactured in accordance with the method described referring to FIG. 1 to FIG. 8. In case of the electronic components 900 shown in FIG. 9, the patterned electrically conductive structure 200 is arranged in between the electrically insulating layer 100 and the electronic chip 300.

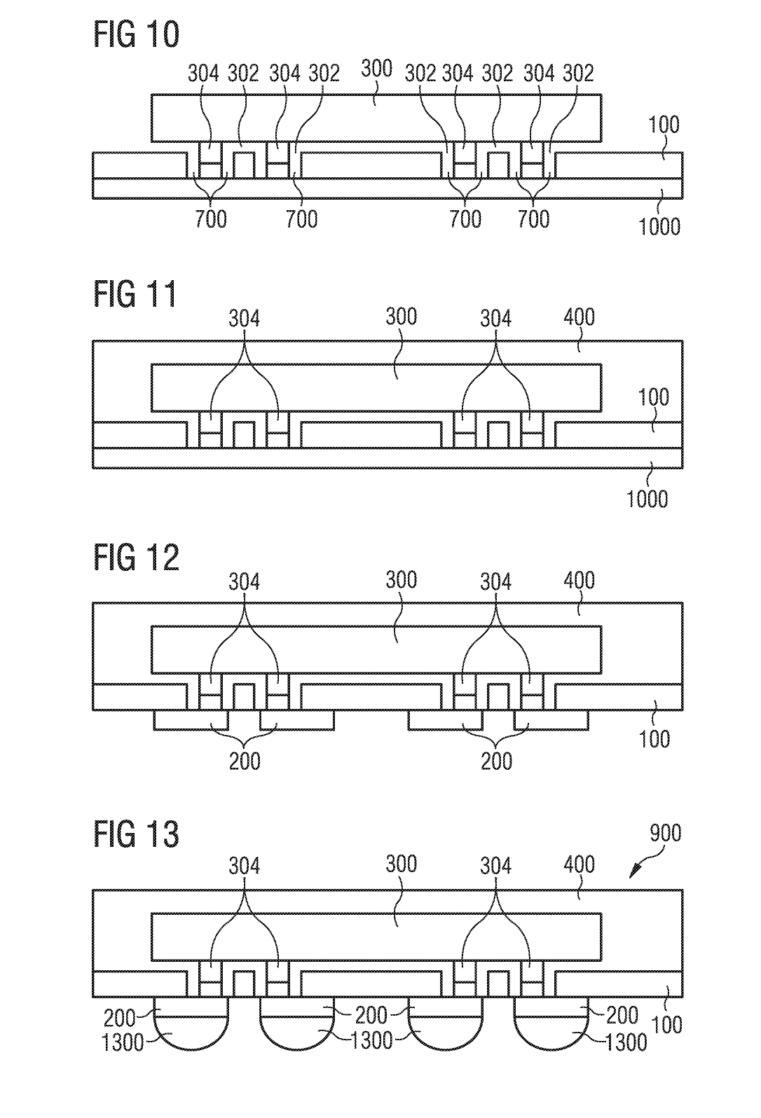

FIG. 10 to FIG. 12 show different structures obtained during carrying out a method of manufacturing an electronic component 900 according to another exemplary embodiment, the latter being shown in FIG. 13. With regard to the embodiment described referring to FIG. 10 to FIG. 13, many of the manufacturing procedures as described above referring to FIG. 1 to FIG. 9 can be implemented, as will be appreciated by those skilled in the art. For the sake of conciseness, only differences will be explained in the following.

In order to obtain a structure shown in FIG. 10, an electrically insulating layer 100 (for instance made of a polymer) and an electrically conductive layer 1000 (for instance functioning as a carrier and being made of thick copper material) are connected to one another. Previously or subsequently, material of the electrically insulating layer 100 is selectively removed, for instance by laser drilling, to thereby form through holes 700 extending vertically through the entire electrically insulating layer 100. An electronic chip 300 comprising electrically conductive intermediate structures 304 (which may be embodied as copper pillars) on an active chip surface may be mounted on the described sandwich composed of the patterned electrically insulating layer 100 and the electrically conductive layer 1000. This may be accomplished by guiding the electrically conductive intermediate structures 304 through the through holes 700 so as to have direct physical contact with the electrically conductive layer 1000. Thus, the electrically conductive intermediate structures 304 may form electrically conductive contact structures extending into and through the through holes 700.

In order to obtain a structure shown in FIG. 11, the electronic chip 300, the patterned electrically insulating layer 100 and the electrically conductive intermediate structures 304 are encapsulated by an encapsulant 400 such as a mold. The material of the encapsulant 400 also fills remaining gaps or voids of the former through holes 700. Hence, to obtain the structure shown in FIG. 11, a die attach procedure and a reflow procedure are carried out, as well as an undermolding procedure.

In order to obtain a structure shown in FIG. 12, the electrically conductive layer 1000 is patterned to thereby form patterned electrically conductive structure 200 on the patterned electrically insulating layer 100. The electronic chip 300 is electrically coupled with the patterned electrically conductive structure 200 via the electrically conductive intermediate structure 304. The electrically conductive intermediate structure 304, hence functioning as electrically conductive contact structure, is in direct physical contact with both the electronic chip 300 and the patterned electrically conductive structure 200. Still referring to FIG. 12, subtractive copper structuring can be carried out. This means that the electrically conductive layer 1000 is patterned by a lithography and etching procedure to thereby obtain a redistribution layer embodying the patterned electrically conductive structure 200.

FIG. 13 shows electronic component 900 manufactured in accordance with the method described referring to FIG. 10 to FIG. 12. The electronic component 900 according to FIG. 13 comprises solder structures 1300 on an exterior surface of the patterned electrically conductive structure 200. Hence, to obtain the electronic component 900 according to FIG. 13, solder material (for instance in the form of solder balls, solder beads or solder paste) may be applied to the redistribution structure in form of the patterned electrically conductive structure 200. According to FIG. 13, the patterned electrically insulating layer 100 is vertically arranged in between the patterned electrically conductive structure 200 and the electronic chip 300. The patterned electrically conductive structure 200 is configured as a redistribution layer forming an interface between small dimensioned chip pads and a larger dimensioned exterior electric interface to be coupled to an electronic periphery (not shown).

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of manufacturing an electronic component, the method comprising:
forming a patterned electrically conductive structure at least partially on an electrically insulating layer;
electrically coupling an electronic chip with the patterned electrically conductive structure;
at least partially encapsulating the electronic chip by an encapsulant;
removing material of the electrically insulating layer to thereby form at least one through hole;
forming at least one electrically conductive contact structure at least partially in the at least one through hole in contact with at least part of the patterned electrically conductive structure.

2. The method according to claim 1, wherein the method further comprises at least partially encapsulating at least one of the group consisting of the patterned electrically conductive structure, and the at least one electrically conductive contact structure.

3. The method according to claim 1, wherein the method further comprises:
forming the patterned electrically conductive structure on or above a temporary carrier, in particular before the encapsulating;
removing the temporary carrier after the encapsulating.

4. The method according to claim 1, wherein the method comprises:
carrying out the procedures of forming the patterned electrically conductive structure, electrically coupling, at least partially encapsulating, removing, and forming the at least one electrically conductive contact structure for manufacturing a plurality of electronic components in a batch procedure;
singularizing an obtained body into the plurality of separate electronic components, each of which comprising part of the electrically insulating layer, part of the patterned electrically conductive structure, part of the encapsulant, at least one electronic chip, and at least one electrically conductive contact structures.

5. The method according to claim 1, wherein the method further comprises removing part of the encapsulant, in particular for one of the group consisting of exposing a main surface of the electronic chip, and for thinning the electronic component.

6. The method according to claim 1, wherein the encapsulating is carried out by at least one of the group consisting of underfilling a gap or void between the electronic chip on the one hand and the electrically insulating layer and the patterned electrically conductive structure on the other hand, and overfilling the electronic chip.

7. The method according to claim 1, wherein the patterned electrically conductive structure is formed by only a single patterning procedure.

8. A method of manufacturing a plurality of electronic components, the method comprising:
forming a patterned electrically conductive structure on or above a temporary carrier;
electrically coupling a plurality of electronic chips with the patterned electrically conductive structure;
at least partially encapsulating the electronic chips and the patterned electrically conductive structure by an encapsulant;
removing the temporary carrier, in particular after the encapsulating;
forming a plurality of electrically conductive contact structures in contact with at least part of the patterned electrically conductive structure;
singularizing an obtained body into the plurality of separate electronic components, each of which comprising part of the patterned electrically conductive structure, part of the encapsulant, at least one of the electronic chips, and at least one of the electrically conductive contact structures.

9. The method according to claim 8, wherein the method further comprises:
forming the patterned electrically conductive structure on an electrically insulating layer;
removing material of the electrically insulating layer to thereby form a plurality of through holes;
forming the electrically conductive contact structures at least partially in the through holes in contact with at least part of the patterned electrically conductive structure.

10. The method according to claim 8, wherein the temporary carrier comprises a metal plate.

11. The method according to claim 8, wherein the temporary carrier is removed, in particular by one of the group consisting of etching, and peeling.

12. An electronic component, the electronic component comprising:
an electrically insulating layer having at least one through hole;
a patterned electrically conductive structure at least partially on the electrically insulating layer;
an electronic chip electrically coupled with the patterned electrically conductive structure;
an encapsulant at least partially encapsulating the electronic chip;
at least one electrically conductive contact structure at least partially in the at least one through hole in contact with at least part of the patterned electrically conductive structure.

13. The electronic component according to claim 12, wherein the encapsulant at least partially encapsulates at least one of the group consisting of the patterned electrically conductive structure, and the at least one electrically conductive contact structure.

14. The electronic component according to claim 12, wherein the electronic chip is mounted on the patterned electrically conductive structure in a flip chip configuration.

15. The electronic component according to claim 12, wherein the patterned electrically conductive structure is configured as one of the group consisting of a patterned double layer stack, and a patterned single layer.

16. The electronic component according to claim 12, comprising an electrically conductive intermediate structure spacing and electrically coupling the electronic chip with regard to the patterned electrically conductive structure.

17. The electronic component according to claim 12, wherein the patterned electrically conductive structure is arranged in between the electrically insulating layer and the electronic chip.

18. The electronic component according to claim 12, wherein the electrically insulating layer is arranged in between the patterned electrically conductive structure and the electronic chip.

19. The electronic component according to claim 12, wherein the patterned electrically conductive structure forms at least part of a redistribution layer constituting an interface between at least one smaller dimensioned chip pad and a larger dimensioned exterior electric interface of the electronic component to be coupled to an electronic periphery.

20. The electronic component according to claim 12, comprising at least one solder structure on an exterior surface of the patterned electrically conductive structure.
